(19) United States
(12) Patent Application Publication
(10) Pub. No.: US 2012/0145229 A1
(43) Pub. Date: Jun. 14, 2012

(54) Irradiating A Plate Using Multiple Co-Located Radiation Sources

(75) Inventors: Jingjia Ji, Jiangsu (CN); Fan Zhu, Jiangsu (CN); Zhengrong Shi, Jiangsu (CN)

(73) Assignee: Wuxisuntech Power Co., Ltd., Jiangsu (CN)

(21) Appl. No.: 13/257,278

(22) PCT Filed: Mar. 17, 2009
(86) PCT No.: PCT/CN09/00285

§ 371 Date: Dec. 6, 2011

(51) Int. Cl. H01L 31/02; B23K 26/08; B23K 26/36; H01L 21/268

(52) U.S. Cl. 136/252; 438/535; 219/121.68; 219/121.78; 219/121.76; 257/E21.347

(57) ABSTRACT

A method for irradiating a plate (104) using multiple co-located radiation sources (108-1,108-2,108-3,108-4) includes that each of the multiple co-located radiation sources (108-1,108-2,108-3,108-4) is responsible for irradiating one of a plurality of bounded sub-regions (110-1,110-2,110-3,110-4) in the plate (104). As a result, sub-regions of the plate (104) that are to be irradiated receive relatively even, relatively well-defined radiation from the multiple co-located radiation sources (108-1,108-2,108-3,108-4). An apparatus performs the method, and a solar cell is produced using the method. The method and the apparatus can be applied in laser doping and laser cutting.

### TECHNICAL FIELD

The present invention relates to irradiating plates with multiple co-located radiation sources, and in particular, to laser scribing a semiconductor wafer or substrate using multiple co-located laser devices.

### BACKGROUND

Radiation from laser can be used in many applications. For example, a thin film of amorphous silicon may be cut in a laser cutting process to form a number of disjoint regions that can be serially connected as a solar electric power cell to provide a suitable voltage to run a hand-held calculator.

In another application, laser radiation can be used to cause dopants to diffuse into a semiconductor wafer or substrate. Specifically, when radiation from a laser is directed at a spot (e.g., a surface spot) on a silicon wafer, an area around that spot warms up, allowing nearby dopants (which may be positioned on top of the silicon wafer as a thin film or in a gaseous state near the surface of the silicon wafer) to diffuse into vicinity of the area. Laser doping as described may be used to create a selective emitter structure on a solar cell. A selective emitter structure comprises selective areas that are relatively highly doped, for example, through a laser doping process previously mentioned. Subsequent metallization of these selective areas of the solar cell forms a low serial resistance contacts in these areas, while other areas that have not been selectively doped form high sheet resistance sunlight-receiving areas. As a result, charges generated in the sunlight-receiving areas can be efficiently collected through the metal in the highly doped areas.

There are a number of disadvantages with laser scribing or doping under existing techniques. Under some of the existing techniques, an object to be irradiated by a laser is placed on a moving stage. To form a particular pattern of irradiation (e.g., parallel lines), the moving stage on which the object is mounted moves within a plane that is substantially vertical to the laser beam during irradiation. Thus, when the stage moves too fast (for example, over 1 meter per second), vibrations from the motion may cause imprecise scribing on the object. For example, where lines should be straight, parallel, and non-crossing, these lines may instead be zigzagged or cross one another inadvertently.

Under some other existing techniques (including those similar to photolithography), an object may be placed in a fixed, stationary position relative to a platform during irradiation. A laser beam from a laser source may be shifted around (e.g., by moving mirrors within a laser device) to create a desired pattern of irradiation on a surface of the object. Typically, the laser beam is in focus only at certain spots on the surface of the object. When the beam moves to different spots, due to the different lengths of optical paths, different incident angles, and other factors involved in the propagation of the beam from the laser source to the object, the beam may be out of focus in these different spots. Consequently, a laser beam may produce uneven intensities of radiation on the object. This shortcoming is worsened if the surface to be irradiated is large.

As applied to making selective emitters on solar cells, a common disadvantage of these existing techniques is uneven concentration of dopant in areas where selective emitters are to be formed. For example, certain areas may be overly doped while other areas may be under-doped. In the worst-case scenarios, undesirable warping, cracks and grooves may be developed on a surface of a semiconductor wafer or substrate, causing serious surface and/or structural damages.

As clearly shown, techniques are needed to increase the speed and improve the quality of irradiation of an object, in particular, as related to irradiation of a semiconductor wafer or substrate by laser light.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

In the drawings:

FIG. 1A, FIG. 1B and FIG. 1C illustrate example configurations of an example system that can be used for irradiating a plate using multiple co-located radiation sources;

FIG. 2A, FIG. 2B, and FIG. 2C illustrate example configurations that can be used to perform laser-enabled selective irradiation; and

FIG. 3 is an example processing flow for irradiating a plate using multiple co-located radiation sources.

### SUMMARY

In some embodiments, a method for irradiating plates comprises: using a first radiation obtained from a first co-located radiation source to irradiate within a first bounded region of a plate, wherein the plate is placed at a first position, wherein the first co-located radiation source is one of a plurality of co-located radiation sources, wherein the first bounded region is one of a plurality of bounded regions of the plate; moving the plate to a second position; and using a second radiation obtained from a second co-located radiation source to irradiate within a second bounded region of the plate, wherein the plate is fixed at the second position, wherein the second co-located radiation source is another one of the plurality of co-located radiation sources, wherein the second bounded region is another one of the plurality of bounded regions of the plate.

In an embodiment, a first intensity of the first co-located radiation source is regulated. In an embodiment, at least one of the plurality of co-located radiation sources is a laser light source. In an embodiment, this laser light source operates at a first wavelength. In an embodiment, the first radiation is a light beam. In another embodiment, the first radiation is a light pattern.

In various embodiments, the plate may be a substrate, a wafer, or generally a planar object (which may have a microscopically uneven surface, for example, one with random pyramids of dimensions of micrometers or fractions of a micrometer). The substrate or wafer may be intended for use in solar power cells or modules, or in semiconductor products. In an embodiment, a thin film of n-type dopants may be placed on top of a light-facing surface of the plate. The first bounded region of the plate may comprise a first layer, which is proximate to a light-facing surface of the plate, and which is lightly doped by n-type dopants. The first bounded region of the plate may further comprise a second layer that is doped by p-type dopants.

In various embodiments, moving the plate to a second position may comprise translating the plate to the second position, rotating the plate to the second position, or a combination of the two.

By logically dividing a substrate or wafer into a finite number of regions, which may be similar or dissimilar, and performing a corresponding number of movements (translation, rotation, or a combination of the two) to allow each of a plurality of co-located radiation sources such as a laser light source to irradiate in each of the regions, the techniques described herein can be easily scaled up to process plates of very large planar dimensions. In this context, “logically dividing” refers to dividing without physically breaking. Since a co-located radiation source only irradiates a particular region of much smaller planar dimensions, intensity of the co-located radiation source absorbed by substrates can be easily regulated for irradiating that particular region. Consequently, structural damages such as warping, cracks and grooves can be avoided or mitigated in this region. Smooth radiation results can be accomplished in this region since the region has much smaller dimensions than those of the plate and defocus of laser beam in this small area becomes less.

In embodiments where a co-located radiation source is a laser light source, the laser light source can be adjusted (e.g., through automatic focusing capability of the optics that is a part of the laser light source) so that much, or all, of a region is within a depth of focus of the laser light source. Well-defined lines of radiation can be created on the region. As applied to creating selective emitter structures on a solar panel, relatively narrow, well-defined lines of metallization and relatively large sunlight receiving areas may be created on the solar cell or panel.

Each co-located radiation source can be independent from others. As a result, the radiation from each such co-located radiation source independently may pass through a different mask pattern or traverse along a different planar trajectory. Since each co-located radiation source may be independent, any two or more co-located radiation sources can be spatially arranged so that a sufficiently large free space can be provided around any of these co-located radiation sources. This facilitates installation, alignment, calibration, maintenance, and operation of such a system.

Various embodiments include a system or an apparatus that implements corresponding embodiments of the method as described above. Various embodiments also include products that are produced using corresponding embodiments of the method as described above. These products include solar cells and/or solar panels.

### DETAILED DESCRIPTION OF THE INVENTION

Techniques for irradiating a plate using multiple co-located radiation sources are described. In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

### A First Example System Configuration

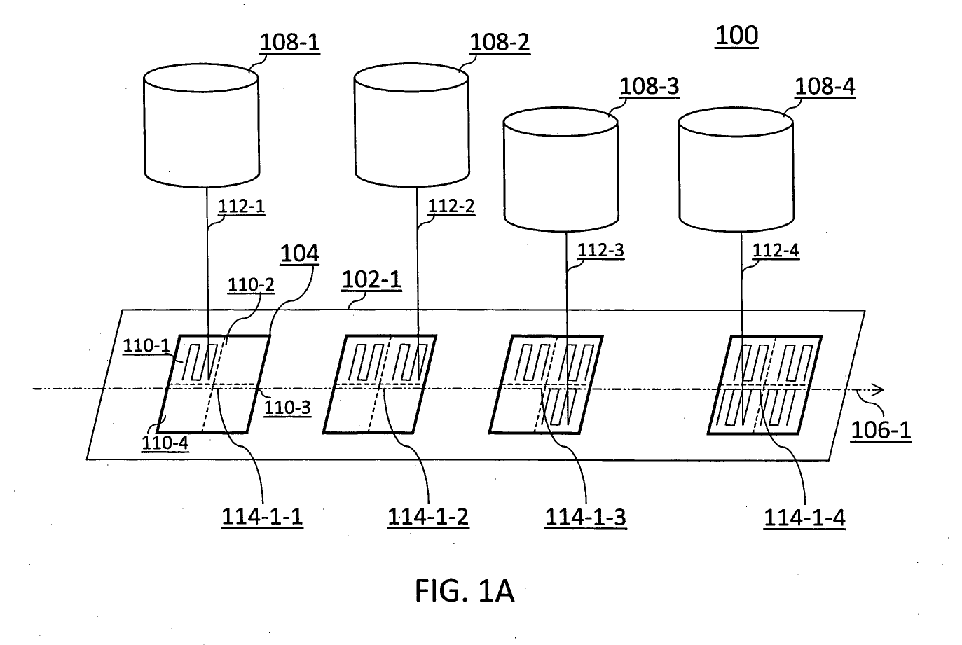

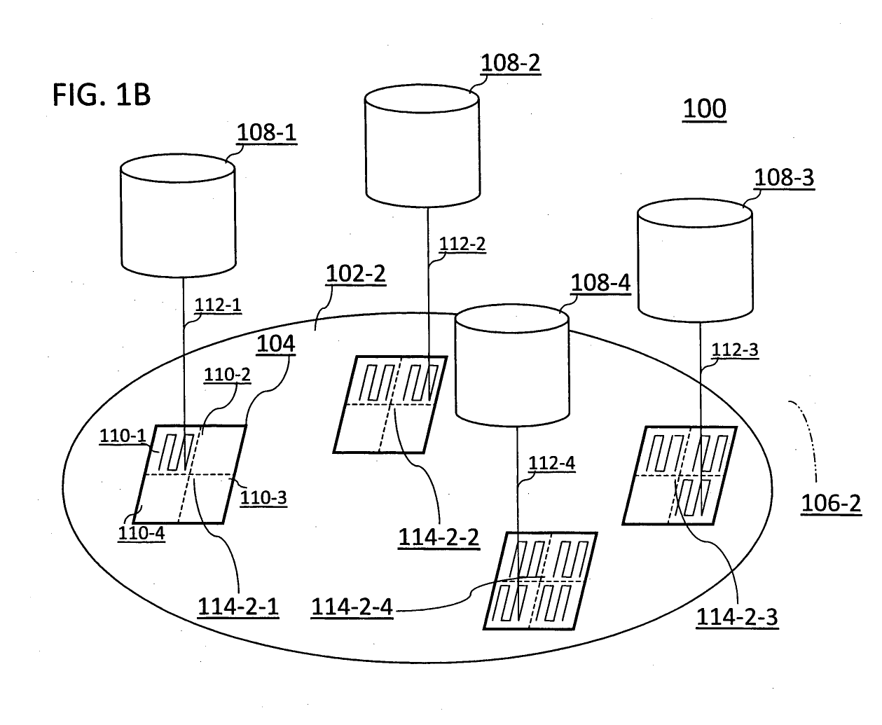

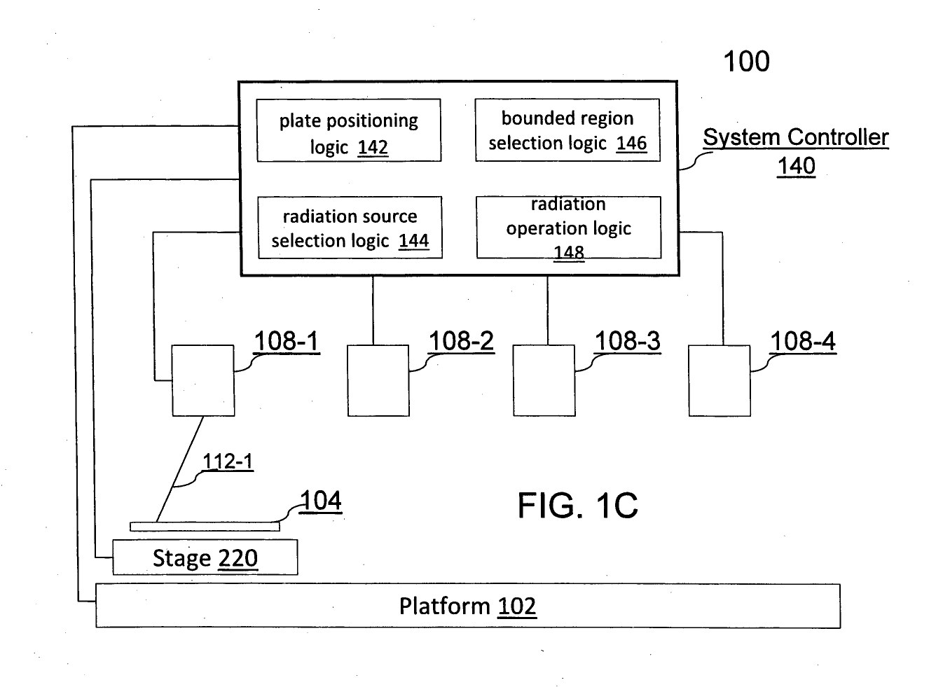

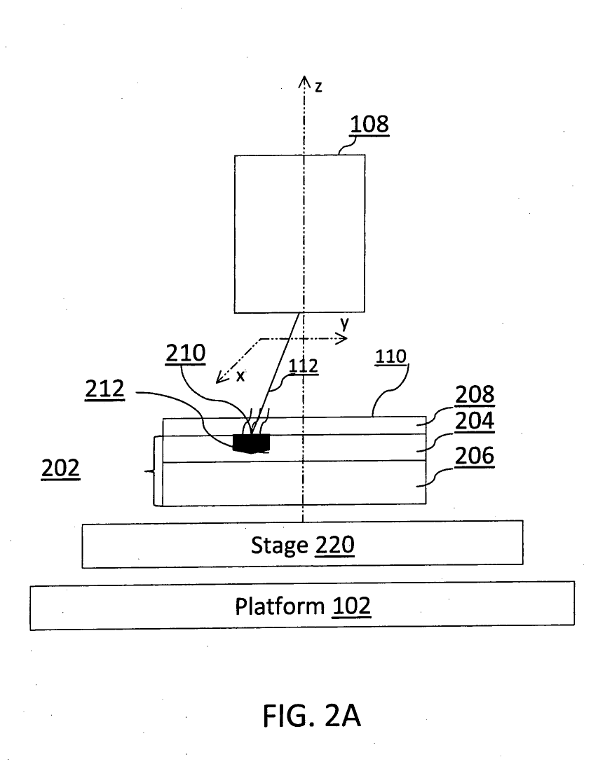

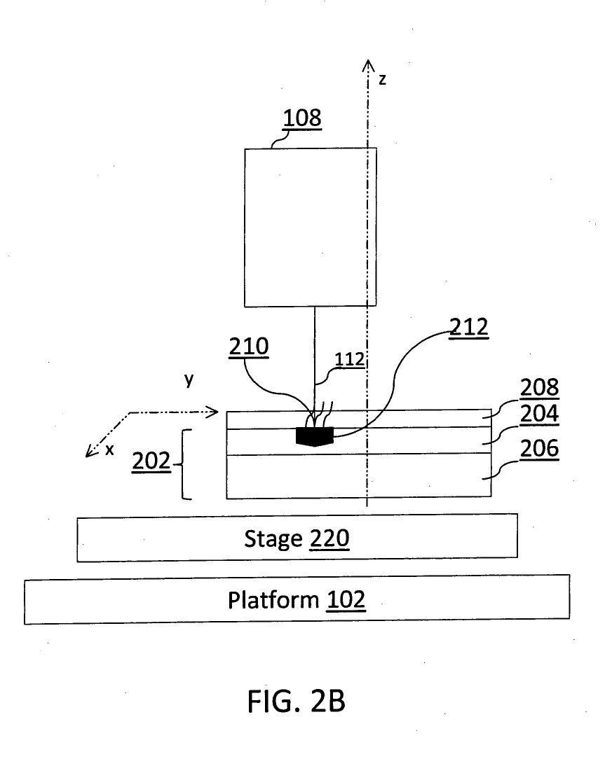

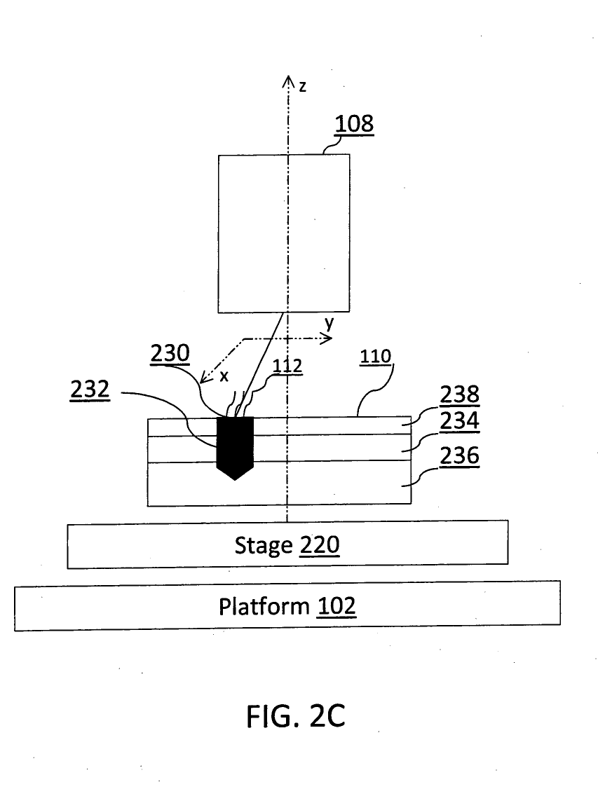

According to an embodiment, as illustrated in FIG. 1A, a system 100 comprises a platform 102-1, two or more co-located radiation sources (e.g., 108-1 through 108-4 as shown). The system 100 may include a stage 220 as illustrated in FIG. 2A and FIG. 2B. A plate 104 may be mounted on the stage. This plate 104 may be irradiated by radiations 112-1 through 112-4 emitted from the two or more co-located radiation sources 108. In some embodiments, as shown in FIG. 1A, the stage may be operable to move along axis 106-1.

As used herein, the term “co-located radiation source” may refer to any device that provides a form of radiation that may be directed at some points or areas of the plate 104. Examples of a co-located radiation source include a laser device, an electron beam device, a particle beam device, an ink jet device, etc. The term “radiation” may refer to coherent light, non-coherent light, an electron beam, a particle beam, ink particles, etc. The term “directed at some points or areas of the plate” means that these points or areas of the plate are irradiated by a radiation (e.g., a laser beam) from a co-located radiation source 108.

In some embodiments, one or more of the co-located radiation sources 108 may be laser light sources. For example, the co-located radiation source 108-2 may be a galvanometer scan laser that provides a laser beam that may be directed at some points or areas of the plate 104.

The plate 104 comprises a surface that receives radiations 112 and into which radiations may penetrate or touch. Types of the plate 104 include, but are not limited to, a substrate, a wafer, and a planar object that is of a material, or of a composite of several materials. In some embodiments, the plate 104 is a thin planar object with a height, in a z dimension that is vertical to the surface of the plate much smaller than either of the plate's planar dimensions (x and y dimensions). For example, the plate 104 may be of a planar dimension of 125 millimeters (hereinafter mm) or 155 mm, while the height of the plate may be 200 micrometers (hereinafter μm).

The plate 104 comprises two or more regions (e.g., 110-1 through 110-4). In one embodiment, these regions 110 may be formed by logically dividing or separating the plate 104 vertically (i.e., in the z-direction) along certain lines, or segments of lines, or shapes such as circles and polygons, represented on the surface of the plate 104. In some embodiments, each of these regions 110 comprises a contiguous, bounded area in the surface that is to receive a radiation 112 from one of the co-located radiation sources 108. In some embodiments, these regions 110 are non-overlapping and may together cover a part, or all, of a surface of the plate 104. In some other embodiments, these regions 110, while each comprising a bounded area, may be partially overlapping with one another.

For the purpose of illustration only, the plate 104 may be logically divided into four regions 110-1 through 110-4 as shown in FIG. 1A.

In some embodiments, system 100 is operable to place the plate 104 at a plurality of positions (e.g., 114-1-1 through 114-1-4) on the platform 102-1. Thus, the positions are stationary relative to the platform 102. These positions 114-1 are aligned with the co-located radiation sources 108 such that one of the co-located radiation sources 108 may irradiate a particular region 110, which is associated with a particular position 114-1 on the platform 102-1, when the plate 104 is placed at the particular position 114-1 on the platform 102-1. In some embodiments, each region (e.g., 110-1) in a plurality of regions 110 of the plate 104 has a one-to-one correspondence to a different position (e.g., 114-1-1) among the positions 114.

For instance, system 100 is operable to place the plate 104 initially at the position 114-1-1. The region 110-1 is associated with this position 114-1-1. When the plate 104 is at position 114-1-1, the co-located radiation source 108-1 that is associated with this position 114-1-1 is operable to irradiate the region 110-1.

Similarly, the system 100 is operable to place the plate 104 at the position 114-1-2. The region 110-2 is associated with that position 114-1-2. When the plate 104 is at position 114-1-2, the co-located radiation source 108-2 that is associated with position 114-1-2 is operable to irradiate the region 110-2. The system may place the plate 104 at positions 114-1-3 and 114-1-4 and cause operation of co-located radiation sources 108-3, 108-4, respectively, at successive times in a similar manner.

In the embodiment of FIG. 1A, regions 110-1 through 110-4 are non-overlapping. Moreover, each of the regions 110 comprises a bounded area on the surface receiving a radiation 112. The term “bounded area” refers to an area that can be placed entirely inside a circle with a finite radius. In some embodiments, the finite radius is less than 75 percent of one of the planar dimensions of the plate 104. In some embodiments, the finite radius is less than 50 percent of one of the planar dimensions of the plate 104. In other embodiments, the finite radius may have other dimensions.

In some embodiments in which at least one of the co-located radiation sources 108 is a laser device, radiation from such a laser device is coherent light. The coherent light may travel along an optical path from the laser source to points and/or areas on the plate 104. Along the optical path, there may be lenses, mirrors, splitters, filters, apertures, masks, or other elements that may affect the optical and/or geometric properties of the light 112. In a particular embodiment, the light 112 may be focused in certain spots (e.g., at a center, at a circle, or a distorted circle, etc) that are located on the plate 104. Therefore, areas on the plate 104 that are irradiated by the light may take a form of fine lines with a finite width, as shown in FIG. 1A. The width may have orders of magnitude of one nanometer, ten nanometers, hundred nanometers, one micrometer, ten micrometers, hundred micrometers, and/or one millimeter. In some embodiments, outside this finite width, any unintended light radiation can be safely ignored.

Other forms of radiation and other types of optics may be provided in zero or more of the co-located radiation sources 108. For example, in some embodiments, instead of using optics that focuses a coherent light into a narrow area, a non-coherent light co-located radiation source may be operable to create a light that is not narrowly focused. In a few of these embodiments, such a light may have a beam width of over 1 mm.

In some embodiments, the positions 114-1 on the platform 102-1 are arranged to permit sufficient free space between the co-located radiation sources 108. In a particular embodiment, neighboring positions 114-1 on the platform 102-1 are selected such that each co-located radiation source 108 is easily installed, operated, replaced, or maintained.

In some embodiments, auxiliary points on the platform 102-1 may be defined. The system 100 may be operable to position, through one or more suitable motions, the plate 104 in one of the auxiliary points. When the plate 104 is positioned at an auxiliary point, the system 100 may be operable to perform one or more actions related to the plate 104. For example, one auxiliary point on the platform 102-1 may be defined and used to load the plate, while another auxiliary point on the platform 102-1 may be defined and used to unload the plate. Yet another auxiliary point on the platform 102-1 may be defined and used to wash the plate.

In some embodiments, while one of the co-located radiation source 108 irradiates the plate 104 at a particular position on the platform 102, other co-located radiation sources 108 may irradiate other plates or planar objects in other positions on the platform 102 at the same time. Thus, multiple plates may be pipelined through a sequence of positions defined on the platform 102 so that various tasks can be performed on the multiple plates in parallel at these positions.

### A Second Example System Configuration

According to an embodiment of the present invention, the techniques may be performed by the system 100 in an alternative configuration as illustrated in FIG. 1B.

In FIG. 1B system 100 comprises a platform 102-2 and co-located radiation sources 108-1 through 108-4. In an embodiment, system 100 comprises a stage 220 (FIG. 2A, FIG. 2B) on which the plate 104 may be mounted to be irradiated by radiations 112-1 112-4 from the co-located radiation sources. In some embodiments, as shown in FIG. 1B, the stage may be operable to rotate the plate 104 through a plurality of positions 114-2-1 through 114-2-4 on the platform 102-2 in a rotational direction 106-2. In some embodiments, if necessary, once the plate 104 is positioned at any of positions 114-2, the stage may be operable to rotate (spin) around that position 114-2 to orient or align the plate 104 with a co-located radiation source that is to irradiate the plate 104 at that position 114-2.

In the embodiments of FIG. 1B, system 100 is operable to place the plate 104 at positions 114-2-1 through 114-2-4 on the platform 102-2. These positions 114-2 are aligned with the co-located radiation sources 108 in such a manner that one of the co-located radiation sources 108 may irradiate a particular region 110 (which is associated with a particular position 114-2 on the platform 102-2) on the plate 104, when the plate is placed at the particular position on the platform.

For instance, system 100 as shown in FIG. 1B is operable to place the plate 104 initially at position 114-2-1. The region 110-1 is associated with this position 114-2-1. When the plate 104 is at position 114-2-1, the co-located radiation source 108-1 that is associated with the position 114-2-1 is operable to irradiate the region 110-1.

Similarly, system 100 as shown in FIG. 1B is operable to place the plate 104 at the position 114-2-2. The region 110-2 is associated with that position 114-2-2. When the plate 104 is at position 114-2-2, co-located radiation source 108-2 that is associated with the position 114-2-2 is operable to irradiate the region 110-2. Analogous operation may be used for the positions 114-2-3 and 114-2-4.

In some embodiments, positions 114-2 on platform 102-2 are arranged to permit sufficient free space between the co-located radiation sources 108. In a particular embodiment, a distance between two neighboring points 114-2 on the platform 102-2 is selected to ensure that each co-located radiation source 108 is easily installed, operated, replaced, or maintained.

As in FIG. 1A, in some embodiments, auxiliary points on the platform 102-2 as illustrated in FIG. 1B may be defined. The system 100 may be operable to position through suitable motions the plate 104 in one of these auxiliary points. At that position, the system 100 may be operable to perform one or more actions related to the plate 104. For example, an auxiliary point on the platform 102-2 may be defined for the purpose of loading the plate. Similarly, another auxiliary point on the platform 102-2 may be defined for the purpose of unloading the plate. Yet another auxiliary point on the platform 102-2 may be defined for the purpose of washing the plate.

### Additional and/or Alternative Configurations

At a position 114, a region 110 on a plate 104 may be irradiated by a co-located radiation source 108. Alternatively, depending on an application of the system 100, at a position 114, the plate 104 may not be irradiated. Furthermore, in some embodiments, at a position 114, system 100 may perform one or more actions other than irradiation, and/or in addition to irradiation. These actions may include, but are not limited to, spinning the plate 104 to a desired orientation in the planar dimensions, aligning a co-located radiation source 108 with the plate, automatically focusing a radiation at a particular depth within, or at a distance away from, the plate, directing a radiation to different points or areas on the plate, and adjusting the intensity of the radiation.

In some embodiments, the system 100 may be operable to step the plate 104 through the positions 114 in a manner such that distances between successive positions are minimized and/or that the number or types of motions involved between successive positions are minimized. For example, in the configuration of FIG. 1A, system 100 may be operable to move the plate 114 in sequence to successive positions along the imaginary straight-line axis 106-1. Each such movement may be denoted a step. Similarly, in the alternative configuration as illustrated in FIG. 1B, the system 100 may be operable to move the plate 114 in sequence along the rotational direction 106-2 to different positions in different steps.

In some embodiments, the co-located radiation sources 108 may be pre-positioned in the system 100 in such a way that spinning around any of the positions 114 is minimized or that the effort involved in aligning the co-located radiation sources 108 and the plate 104 is minimized.

In some embodiments, the laser device may optionally and/or additionally comprise modulation devices, amplifiers, drivers, and control logic. FIG. 1C is a block diagram that illustrates an example configuration of system 100, which comprises a system controller 140. System controller 140 is operatively linked to other parts of system 100, such as the radiation sources 108, the stage 220, and/or the platform 102 and controls and coordinates operations of various parts of system 100 for the purpose of obtaining status of and exercising control over these other parts of system 100. In some embodiments, system controller 140 comprises plate positioning logic 142 that controls a conveyance mechanism to move the plate 104 to various positions 114 on the platform 102, radiation source selection logic 144 that selects a radiation source 108 for a particular position 114, bounded region selection logic 146 that determines which bounded region/area is to be radiated on, and radiation logic 148 that controls a radiation 112 by the selected radiation source over the selected bounded region at the particular position 114.

### Example Laser Scribing

In some embodiments, the co-located radiation sources 108 of FIG. 1A and FIG. 1B are laser light sources. The plate 104 is a single semiconductor wafer that undergoes a manufacturing process to become a part of a solar panel product. As part of this manufacturing process, as shown in FIG. 2A, a region 110 of the plate 104 (e.g., 110-2 of FIG. 1A or FIG. 1B) may be placed in position for radiation from a laser light source 108 (in this example, 108-2 of FIG. 1A or FIG. 1B) when the plate 104 is placed at the position 114-1-2 of FIG. 1A or at the position 114-2-2. In some embodiments, the plate 104 including the region 110 is mounted on a stage 220, which may be fixed, or moved relative to, relative to a platform 102 (which may be 102-1 of FIG. 1A or 102-2 of FIG. 1B).

Referring now to FIG. 2A, the irradiation of the region 110 by the laser light source 108 is one of a plurality of phases in a manufacturing process to create one or more high doped areas in the region 110, in order to enhance the solar panel product's ability to collect electric charges in the region when the product is deployed in the field.

The region 110 or the semiconductor wafer may initially comprise two layers 204, 206 that form a photovoltaic p-n junction. A first layer is a p-type conductivity layer 206 and the second layer is an n-type conductivity layer 204. In some embodiments, in order to increase the sheet resistance, the n-type conductivity layer 204 is relatively lightly doped with a suitable type of n-dopants and thus may be denoted as an n⁻ layer. However, variations of n-type of doping in the layer 204 at various concentration levels of n-type dopants may be used in different embodiments.

As a part of creating the selective emitter structure, the system 100 may be operable to first create a structure 212 with a relatively high n-dopant concentration, denoted as an n⁺ structure. Thus, the system 100 may be used to perform laser doping in selected sub-regions of the region 110 of the semiconductor wafer 104.

In some embodiments, a thin film 208 containing n-dopants may first be formed on top of the n⁻ layer 204. Subsequently, the laser light source 108 is operable to send radiation 112 in the form of a laser beam that focuses at a spot 210 of the semiconductor wafer 104. As result of this radiation 112, a sub-region of the wafer near the spot 210 receives a heat shock, in the form of a rapid raising and subsequent lowering of temperature, causing the n-dopants contained in the thin film 208 to diffuse inside the n⁻ layer 204 near the spot 210, thereby creating the structure 212 with a relatively high concentration of n-dopants.

In some embodiments, the laser light source 108 is a galvanometer scan laser. The laser light source 108 is operable to shift the incident direction of the laser beam 112 to various points in the x-y plane that is vertical to the z axis. In some embodiments, the structure 212 that has a relatively high concentration of n-dopants appears as interconnected parallel lines on the region 110, as viewed from the vertical direction (along the −z axis) to the plate 104.

Metal lines may thereafter be deposited over the n⁺ structure 212, as created by the laser doping described above. The deposition of metal over the n⁺ structure 212 may be done using a suitable metallization technique including but not limited to electroplating or electroless plating. In some embodiments, these metal lines form electrically interconnected connected lines. In various embodiments, various interconnection patterns may be used. As a result, selective emitter structures with a relatively low serial resistance may be created in the region 110 of the plate 104.

### Example Semiconductor Wafers

In various embodiments, the semiconductor wafer 104 may be either mono-crystalline, polycrystalline, or amorphous silicon, or other materials such as TCO. In some embodiments, the height of the region 110 in the plate 104 is between 50 μm and 5 mm. In a particular embodiment, this height is 100-300 μm.

In some embodiments, typical planar dimensions of the region 110 may be between 10 mm and 300 mm. In a particular embodiment, such a planar dimension is 100-200 mm. In some embodiments, the height of the n⁻ layer 204 is between 0.1 μm and 3 μm. In a particular embodiment, this height is 0.3 μm.

In some embodiments, the thickness of the thin film 208 of dopants is between 1 nanometer (hereinafter nm) and 1000 nm. In a particular embodiment, this thickness is 100 nm.

In some embodiments, the laser beam 112 from the laser light source 108 is non-pulsed. However, in some other embodiments, the laser beam 112 from the laser light source 108 is pulsed with a frequency that is suitable for a particular application of the system 100.

In various embodiments, the p layer 206 is doped with suitable p-type dopants at various levels of concentrations. In a particular embodiment, the p layer 206 is doped with boron ions B⁺ with a concentration level of 1*10^{15˜1*10}¹⁶.

In various embodiments, the n⁻ layer 204 is doped with suitable n-type dopants. In a particular embodiment, then layer 204 is doped with 5*10^{16˜5*10}²⁰.

### Example Laser Light Sources

In some embodiments, the laser beam 112 has an intensity that is regulated within a range of power values. As used herein, the term “intensity” means an average intensity used to irradiate a spot (which may be of a width of several mm, a fraction of mm, several nm, several tens or hundreds of nm, etc. depending on applications) for a duration (which may be a time period of several nanoseconds, several tens of nanoseconds, several hundreds of nanoseconds, etc. depending on applications). In an embodiment, the intensity is limited by an upper bound value. In another embodiment, the intensity is limited by a lower bound value. In some embodiments, this intensity may be of several hundred watts to several kilowatts. Depending on applications of new techniques as described herein, the intensity may be of other values (e.g., several tens of watts, several watts, several tens of kilowatts, etc.). In some embodiments, the laser beam 112 may, but is not limited to, be generated from a commercially available Nd:YAG laser system.

In some embodiments, the laser beam 112 is polychromatic, comprising a plurality of wavelengths. In some other embodiments, the laser beam 112 is monochromatic and of a single wavelength whose value, for example, falls between 100 nm and 2200 nm. In a particular embodiment, this wavelength is within a range of wavelength such as between 500 nm and 1000 nm, inclusive. For some applications, this single wavelength is greater than a threshold wavelength. For some other applications, this single wavelength is lower than a threshold wavelength.

It should be noted that values as described herein are for illustration purposes only. For example, other wavelengths and other power ratings of a laser light source may be also used, depending the types of applications that use new techniques as described herein.

In some embodiments, the system 100 (or the laser light device 108 therein) is operable to focus the laser beam 112 at the center of the region 110. In some other embodiments, the laser light device 108 is operable to focus the laser beam 112 at a spot that is different from the center of the region 110. In these other embodiments, for example, the laser beam 112 may focus at the spot 210 as shown in FIG. 2A. In example embodiments, the focus spot may be between 0 mm and 100 mm away from the center of the region 110. In an example embodiment, the focus spot is 70 mm away from the center.

In some embodiments, instead of focusing at a spot (e.g., 210 of FIG. 2A) right on the upper surface of the plate 104, the laser beam 112 may focus at a spot that is above or below the spot on the surface. In some embodiments of laser doping, the focus of the laser beam may be at a spot that is slightly above or below the surface through which the radiation enters. The distance between the focused spot and the surface may be between 0 nm and 1 mm.

In some embodiments, the optics of the laser light source 108 is of a depth (of focus) within which the laser beam 112 is deemed as focused. As the laser beam 112 scans the region 110, some sub-regions in the region 110 may or may not be located within the depth of focus of the laser light source. Thus, in some embodiments, the region 110 is entirely within the depth of focus, for example, when the region 110 is small enough so as to be within the capability of the optics of the laser light source 108.

In some other embodiments where the region 110 is large enough so that irradiating some sub-regions of the region 110 exceeds the capability of the optics of the laser light source 108. In some embodiments, as only a portion of the region 110 lies within the depth of focus, irradiation of the laser beam on various spots of the region 110 may not be completely uniform. In some other embodiments, the system 100 is operable to restrict irradiating the plate 104 to sub-regions of the region 110 within its depth of focus.

The techniques herein can be used to create selective high n-doped sub-regions in a region 110 of FIG. 2A of a semiconductor wafer that comprises an n layer and a p layer. In other embodiments, the techniques herein can be used to cut a contiguous thin film that has been formed on a glass substrate. Using multiple co-located radiation sources to radiate multiple regions of a plate that is movable to various positions may be applied for other purposes and products.

For the purpose of illustrating a clear example, each radiation 112 at a particular position 114 has been described as using a separate co-located radiation source 108. However, in other embodiments, a common co-located radiation source 108 may be used to provide two or more radiations 112. For example, in an alternative embodiment where a co-located radiation source 108 is a laser light source, a light from such a laser light source may be split, additionally and/or alternatively redirected, to provide lights at two or more positions 114.

### Example Configuration Using a Stationary Laser

FIG. 2B illustrates irradiating a region 110 of the plate 104 for laser doping applications using a stationary laser. In FIG. 2B, the laser beam 112 is stationary with respect to the laser light source 108 and to the platform 102. Thus, the laser beam 112 does not shift its direction within the x-y plane that is vertical to the z-axis (which is normal to the light-facing surface of the region 110). For example, the laser beam 112 may maintain a direction that is vertical to the region 110.

In this alternative, the stage may make relative motions in the x-y plane relative to and about the position 114 to which the plate 104 is placed so that the region 110 (e.g., 110-1-2 of FIG. 1A) as shown in FIG. 2B is irradiated by a corresponding laser light source 108 (i.e., 108-2 of FIG. 1A) as shown in FIG. 2B. These relative motions with reference to the position 114 may be made in a particular manner so that a desired radiation pattern is made on the region 110.

### Some Other Example Applications

An application of creating a highly doped structure with n-type dopants on a plurality of regions of a single plate is just one example application. It should be noted, however, the present invention is not so limited. Techniques as described herein can be used in many other applications. For example, another application may be creating a highly doped area or region with p-dopants using techniques as described herein. Furthermore, other applications using techniques as described herein are within the scope of the present invention.

FIG. 2C illustrates another example application in which irradiation of a region 110 by a laser light source 108 is one of a plurality of phases in a manufacturing process to create laser fired contacts in the region 110 (as in other figures, FIG. 2C is provided for illustration purposes only; dimensions in FIG. 2C are not necessarily proportionally drawn from actual systems).

The region 110 may be initially a semiconductor wafer comprising a p-type conductivity layer and an n-type conductivity layer. Although only the p-type conductivity layer is illustrated as 236 of FIG. 2C, it may be understood that the n-type conductivity layer may be situated proximate to and right below the p-type conductivity layer in FIG. 2C. In some embodiments, in order to reduce loss of solar energy and to create surface passivation, a dielectric reflective layer 234 with a suitable refractive index may be placed on top of the p-type conductivity layer 236 (the top surface of which is a rear surface of a solar cell when deployed in the field). This dielectric reflective layer 234 may be of a thickness of, for example, 5 nm to 300 nm (other thickness may also be used). In some embodiments, this dielectric reflective layer 234 may be made of sub-layers. In a particular embodiment, this dielectric reflective layer 234 may comprise a sub-layer of PECVD-SiNₓ and another sub-layer of PECVD-SiOₓ, with various thickness dimensions of the sub-layers (not illustrated in FIG. 2C).

In some embodiments, an aluminum layer 238 is pre-deposited on top of the dielectric reflective layer 234. To provide an efficient positive electrode to the photovoltaic junction formed by the n-type conductivity layer and the p-type conductivity layer, a good metallic connection between the aluminum layer 238 and the p-type conductivity layer 236 (through the dielectric reflective layer) may be desired. In some embodiments, the system 100 may be operable to create laser fired contacts (LFCs) between the aluminum layer 238 and the p-type conductivity layer structure 236 through the dielectric reflective layer 234.

For example, with a radiation 112, a sub-region of the wafer near the spot 230 receives a heat shock, causing metallic materials in the aluminum layer 238 to penetrate the dielectric reflective layer 234 near the spot 230 and to reach inside the p-type conductivity layer (silicon) 236, thereby creating a laser fired contact 232 at the spot 230.

In some embodiments, the laser light source 108 may be a pulsed galvanometer scan laser. The laser light source 108 is operable to shift the incident direction of the laser beam 112 to various points in the x-y plane that is vertical to the z axis. In some embodiments, as the laser beam 112 moves, a plurality of laser fired contacts may be created in the region 110.

In some embodiments, instead of using a laser beam such as 112 illustrated in FIG. 2C, a suitable optical mask may be used to create a pattern on the top surface of the aluminum layer/film 238. For example, the pattern may be formed as a grid of points in the region 110. Only these points are simultaneously irradiated with laser light. In these embodiments, a plurality of laser fired contacts may be created simultaneously. In various embodiments, various LFC patterns may be used and formed in the region 110. As a result, an efficient positive electrode may be created in the region 110 of the plate 104 in the rear side (i.e., the top surface as shown in FIG. 2C) of a solar cell.

### Example Process Flow

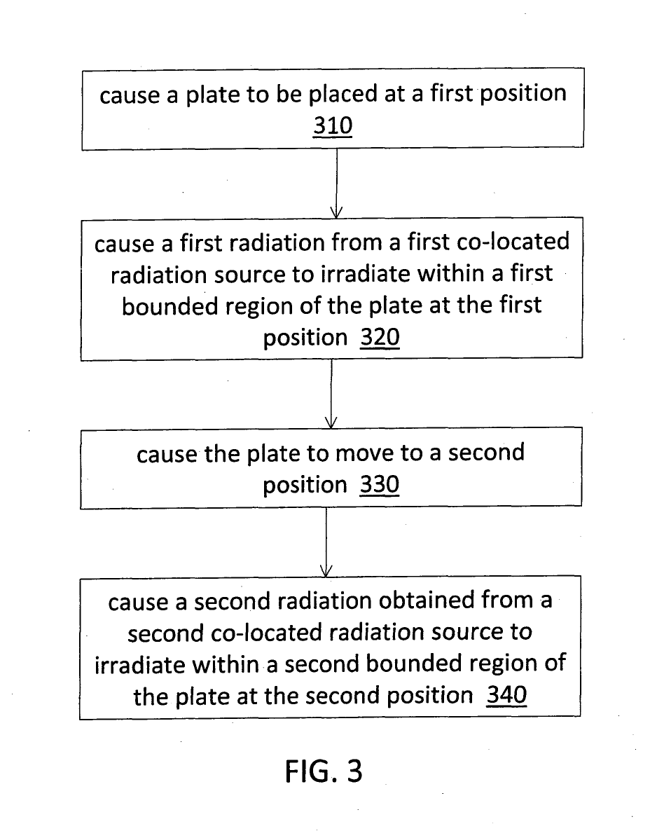

FIG. 3 illustrates an example process of irradiating a plate (e.g., 104) using a system such as 100 of FIG. 1A or FIG. 2A. For the purpose of illustrating a clear example, FIG. 3 is described with reference to FIG. 1A, FIG. 1C, and FIG. 2A.

In block 320, the system 100 is operable to invoke the plate positioning logic 142 to cause the plate 104 to be placed at a first position 114-1-1.

In block 320, the system 100 is operable to cause a first radiation from a first co-located radiation source to irradiate within a first bounded region of a plate 104. For example, in block 320, the system 100 may invoke radiation selection logic 144 to select the first co-located radiation source in the plurality of co-located radiation sources. The system 100 may also invoke bounded region selection logic 146 to determine that the region to be irradiated on is the first bounded region of the plate 104. The first bounded region 110-1 is one of a plurality of bounded regions of the plate 110-1 through 110-4.

In some embodiments, the system 100 may invoke radiation operation logic 148 to provide a radiation 112-1 in the form of a laser beam from a co-located radiation source 108 to irradiate within a first bounded region 110-1 of plate 104.

In the present example, irradiation of the first bounded region 110-1 by the first light source occurs before irradiation of other regions 110-2 through 110-4. However, in other embodiments, one or more other regions 110 may have already been irradiated before the first bounded region 110-1 is irradiated in block 320.

In block 330, the plate is moved to a second position. For example, the system 100 is operable to invoke the plate positioning logic 142 to cause the plate 104 to be placed at a second position 114-1-2. This occurs, for example, in response to that the system 100 has finished irradiating the region 110-1 at the position 114-1-1. In some embodiments, during moving the plate 104 from one position to another position, the system 100 is operable to avoid and/or prevent irradiating any spot of the plate 104 by any radiation source 108. In a particular embodiment, when the plate 104 is being moved from one position to the next position, some or all of the radiation sources 108 may be in a state in which there is no radiation (e.g., laser light) being emitted by the radiation sources 108.

In some embodiments, the plate is mounted on and fixed relative to a stage. Moving the stage to the second position may include translating the stage to the second position, or rotating the stage to the second position, or moving the stage to the second position using both rotation and translation. In some other embodiments, other types of conveying mechanisms (e.g., a conveyor belt) other than a stage type may be used. In still other embodiments, one or more stages may be combined with one or more conveying mechanisms of one or more other types. For example, in some embodiments, a conveyor belt is used to move a stage from one position to another position while the stage is used to make planar motions relative to a position.

In some embodiments where a light (e.g., 112-2) from a laser light source (e.g., 108-2) can shift its incident direction in the x-y plane during irradiating the plate 104, as shown in FIG. 2A, the system 100 is operable to cause the plate 104 to be fixed at a position (e.g., 114-1-2) of, and stationary relative to, the platform 102 during irradiating by the laser (i.e., 112-2) at the position (i.e., 114-1-2).

In block 340, a second radiation from a second co-located radiation source is used to irradiate within a second bounded region of the plate. For example, regardless of whether the stage (or another mechanism) on which the plate 104 is mounted can move relative to the position 114-1-2 during irradiating the plate 104 at that position, the system 100 is operable to use a second light (which, for example, may be a laser beam 112-2) obtained from a second light source 108-2 (which, for example, may be a laser device) to irradiate within a second bounded region 110-2 of the plate 104. As illustrated, the second light source 108-2 is different from the first light source 108-1 among the plurality of light sources 108. The second bounded region 110-2 is different from the first bounded region 110-1 among the plurality of bounded regions 110 of the plate 104.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

1. A method for irradiating plates, comprising:
causing a plate to be placed at a first position;
causing a first radiation from a first co-located radiation source to irradiate within a first bounded region of the plate at the first position, wherein the first co-located radiation source is one of a plurality of co-located radiation sources positioned over a platform that carries the plate, wherein the first bounded region is one of a plurality of bounded regions of the plate;
causing the plate to move to a second position; and
causing a second radiation obtained from a second co-located radiation source to irradiate within a second bounded region of the plate at the second position, wherein the plate is fixed at the second position, wherein the second co-located radiation source is a different one of the plurality of co-located radiation sources, wherein the second bounded region is a different one of the plurality of bounded regions of the plate.

2. The method of claim 1, wherein the first radiation is a light beam.

3. The method of claim 1, wherein the first radiation is a light pattern.

4. The method of claim 1, wherein at least one of the plurality of co-located radiation sources is a laser light source.

5. The method of claim 1, wherein moving the plate to a second position comprises translating the plate to the second position.

6. The method of claim 1, wherein moving the plate to a second position comprises rotating the plate to the second position.

7. The method of claim 1, wherein a first intensity of the first co-located radiation source is regulated.

8. The method of claim 1, wherein the first co-located radiation source is a laser light source operating at a first wavelength.

9. The method of claim 1, wherein the plate is a substrate.

10. The method of claim 1, wherein the plate is a wafer.

11. The method of claim 1, wherein the first radiation is a laser light, further comprising placing a film of n-type dopants on top of a first surface of the plate that faces the laser light.

12. The method of claim 1, wherein the first radiation is a laser light, wherein the first bounded region of the plate comprises a first layer that is lightly doped by n-type dopants, wherein the first layer is proximate to a first surface of the plate, and wherein the first surface faces the laser light.

13. The method of claim 12, wherein the first bounded region of the plate further comprises a second layer that is doped by p-type dopants.

14. The method of claim 1, wherein the first radiation is a laser light, further comprising placing a dielectric reflective layer on top of a first surface of the plate that faces the laser light and placing a metallic back surface field layer on top of the dielectric reflective layer.

15. The method of claim 1, wherein the first radiation is a laser light, wherein the first bounded region of the plate comprises a first layer that is doped by p-type dopants, wherein the first layer is proximate to a first surface of the plate, and wherein the first surface faces the laser light.

16. The method of claim 15, wherein the first bounded region of the plate further comprises a second layer that is doped by n-type dopants.

17. An apparatus for laser scribing, comprising:
a platform;
a stage on which a plate is relatively fixed, wherein the stage is operable to move the plate to each position in a plurality of positions relatively stationary on the platform so as to cause the plate to be irradiated by a radiation from a co-located radiation source at each such position; and
a plurality of co-located radiation sources, wherein a first co-located radiation source in the plurality of co-located radiation sources is operable to irradiate only in a first bounded region of a plurality of bounded regions of the plate and wherein each of the plurality of bounded regions of the plate corresponds to one different position in the plurality of positions.

18. The apparatus of claim 17, wherein said first co-located radiation source is a light beam.

19. The apparatus of claim 17, wherein said at least first radiation source is a light pattern.

20. The apparatus of claim 17, wherein said first co-located radiation source is a laser light source.

21. The apparatus of claim 17, wherein the stage is operable to perform a translation in order to cause the plate to be moved from a first position to a second position, and wherein the first position and the second position are two different points in the plurality of positions.

22. The apparatus of claim 17, wherein the stage is operable to perform a rotation in order to cause the plate to be moved from a first position to a second position, and wherein the first position and the second position are two different points in the plurality of positions.

23. The apparatus of claim 17, wherein an intensity of said first co-located radiation source is regulated.

24. The apparatus of claim 17, wherein said first co-located radiation source is a laser light source operating at a first wavelength.

25. The apparatus of claim 17, wherein the plate is a substrate.

26. The apparatus of claim 17, wherein the plate is a wafer.

27. The apparatus of claim 17, wherein said first radiation is a laser light, wherein a thin film of n-type dopants is placed on top of a first surface of the plate, and wherein the first surface faces the laser light.

28. The apparatus of claim 17, wherein said first radiation is a laser light, wherein the first bounded region of the plate comprises a first layer that is lightly doped by n-type dopants, wherein the first layer is proximate to a first surface of the plate, and wherein the first surface faces the laser light.

29. The apparatus of claim 28, wherein the first bounded region of the plate further comprises a second layer that is doped by p-type dopants.

30. The apparatus of claim 17, wherein said first radiation is a laser light, wherein a dielectric reflective layer is placed on top of a first surface of the plate, wherein a metallic back surface field layer is placed on top of the dielectric reflective layer, and wherein the first surface faces the laser light.

31. The apparatus of claim 17, wherein said first radiation is a laser light, wherein the first bounded region of the plate comprises a first layer that is doped by p-type dopants, wherein the first layer is proximate to a first surface of the plate, and wherein the first surface faces the laser light.

32. The apparatus of claim 31, wherein the first bounded region of the plate further comprises a second layer that is doped by n-type dopants.

33. A product that is produced using the method in accordance with claim 1.

34. A solar cell that is produced using the method in accordance with claim 1.
